(19) United States
(12) Patent Application Publication
(10) Pub. No.: US 2017/0314133 A1
(43) Pub. Date: Nov. 2, 2017

(54) PLASMA REACTOR HAVING DIVIDED ELECTRODES

(71) Applicant: RETRO-SEMI TECHNOLOGIES, LLC, BEVERLY, MA (US)

(72) Inventors: Dong-Soo KIM, Yong In-Si (KR); Min-Su Joo, Youn In-Si (KR)

(21) Appl. No.: 15/484,718

(22) Filed: Apr. 11, 2017

Related U.S. Application Data
(60) Provisional application No. 62/329,488, filed on Apr. 29, 2016.

(51) Int. Cl. C23C 16/505; C23C 16/458; C23C 16/455; C23C 16/52; H01J 37/32

(52) U.S. Cl. CPC C23C 16/505; H01J 37/32082; H01J 37/32532; C23C 16/455; C23C 16/52; C23C 16/458; H01J 2237/3321

(57) ABSTRACT

A plasma reactor for generating a plasma for use in depositing a thin film on a large area wafer, such as in the manufacturing of solar cells. A plasma electrode unit in the plasma reactor is divided into a plurality of discrete electrodes, and RF electric power is sequentially applied to the divided plasma electrodes in accordance with a phase angle detected by a phase control unit. The sequential application of high frequency RF power across the divided plasma electrode unit resolves a standing wave problem in the plasma applied over a large area corresponding to a large area wafer.

### STATEMENT REGARDING FEDERALLY SPONSORED RESEARCH OR DEVELOPMENT

n/a

### BACKGROUND OF THE INVENTION

Chemical vapor deposition (CVD) technology, used in a process for manufacturing an integrated circuit (IC) such as a semiconductor, is a technique which applies energy such as heat or electric power to a gaseous raw material including chemicals to increase a reactivity of the raw material gas and induce a chemical reaction, so that a raw material gas is adsorbed on a semiconductor wafer to form a thin film or an epitaxial layer, and is mainly used to produce a semiconductor, a silicon oxide film, a silicon nitride film, or an amorphous silicon thin film.

In general, the yield rate of a semiconductor is improved if production occurs at a relatively lower temperature during a manufacturing process because the number of product defects are reduced. However, chemical vapor deposition technology causes a chemical reaction by applying energy with heat or light, so that the temperature inevitably increases, making it difficult to improve the yield rate of the semiconductor.

As an approach to solving the temperature-induced defects problem, a plasma enhanced chemical vapor deposition (PECVD) method enables chemical vapor deposition even at a low temperature. In the PECVD method, a chemical reaction is induced to deposit a thin film by chemically activating a reactant using plasma instead of applying heat, electricity, or light to increase the reactivity of the raw material gas. To achieve this in PECVD, chemical activity is improved to generate a chemical reaction at a low temperature by supplying RF electric power from an RF oscillator to a raw material gas existing in a gaseous state, thereby converting the reactant into plasma.

Generally, a higher deposition speed can be obtained using the PECVD method as frequency of the RF power becomes higher. At a very high frequency (VHF) condition, the high deposition speed increases, resulting in an improvement in productivity, efficiently reducing manufacturing costs in semiconductor manufacturing processes. Accordingly, it is common to perform the PECVD processing under a VHF conditions to improve manufacturing efficiency. For example, RF frequency is typically provided by an RF oscillator at a high frequency of 10 MHz or higher, and preferably, 13.56 MHz, 27.12 MHz, or 40.68 MHz.

The PECVD process performed in typical semiconductor manufacturing may be performed under high frequency conditions because semiconductor wafers are relatively small. However, when a semiconductor wafer is large, for example, when the wafer is larger than the semiconductor wafer used in typical processes, such as for solar cell manufacturing, there occurs a problem in which it is difficult to constantly maintain a wide plasma corresponding to the large area wafer surface. In other words, a plasma non-uniformity problem exists with larger wafers.

The non-uniform plasma is caused by a standing wave due to a large area wafer used in a solar cell manufacturing process. The standing wave is a combination of waves occurring when waves having the same amplitude and frequency are moved in opposite directions, and refers to a wave that only vibrates in the stopped state but does not proceed. Accordingly, because the intensity of RF power on a surface of an electrode varies due to standing waves formed along a surface of the plasma electrode, the plasma lacks uniformity.

Due to the non-uniformity of plasma occurring due to a standing wave in a plasma reactor under a high frequency condition, characteristics and deposition rate or etching rate of a thin film, formed at a site where the density of plasma is relatively low, differs as compared with a site where the density of plasma is high, so that entire productivity of such larger wafers is compromised.

### BRIEF SUMMARY OF THE INVENTION

The present invention relates to a plasma reactor and, more particularly, to a plasma reactor used for generating a plasma for use in manufacturing products having a large wafer surface area, such as a thin film solar cell. A plasma electrode unit in a plasma reactor is divided into a plurality of parts and RF electric power is sequentially applied to the divided plasma electrode parts in response to a determined phase angle to solve a standing wave problem on the plasma electrode. Absent the divided plasma electrode, high frequency RF electric power applied to form the plasma over a large area corresponding to the large wafer surface area can result in plasma imbalance due to a standing wave phenomenon.

According to an aspect of the present invention, there is provided a plasma reactor for processing plasma, the plasma reactor comprising a plasma electrode unit divided into a plurality of parts or electrodes, a process gas inlet for injecting a process gas to a lower portion of the divided plasma electrode unit, a wafer disposed at a lower end of the plasma electrode unit and on which the process gas converted into plasma is deposited, an RF electric power unit for supplying RF electric power, and a phase control unit for sequentially applying RF electric power to each of the divided parts of the plasma electrode unit.

The phase control unit matches the divided parts of the plasma electrode unit with specific phase angles of the RF electric power in advance, and receives RF electric power from the RF electric power unit, detects a phase of the RF electric power, and applies the RF electric power to the divided parts or electrodes of the plasma electrode unit matched with the detected phase angle of the RF electric power.

The divided plasma electrode unit includes at least a first plasma electrode, a second plasma electrode, a third plasma electrode, and a fourth plasma electrode that are spaced apart from each other. The phase control unit sequentially matches the divided parts of the plasma electrode unit with the phase angles of 0° (360°), 90°, 180°, and 270° of the RF electric power to set the plasma electrode unit in advance.

The divided parts or electrodes of the plasma electrode unit are spaced apart from each other at the same interval in correspondence to the shape of the wafer and are horizontally disposed in the same plane, in parallel, and are insulated from each other through an insulator.

The plasma reactor further includes a plurality of process gas inlets for injecting a process gas into the divided parts of the plasma electrode unit.

The plasma reactor further includes a chamber including a partition wall extending downwards such that the process gas injected to lower portions of the divided parts or electrodes of the plasma electrode unit is shielded, and the chamber is opened downwards for depositing the formed plasma on the wafer disposed below.

It should be understood that different embodiments of the invention, including those described under different aspects of the invention, are meant to be generally applicable to all aspects of the invention. Any embodiment may be combined with any other embodiment unless inappropriate. All examples are illustrative and non-limiting.

The plasma reactor having the divided electrodes according to the present invention solves a standing wave problem and a plasma imbalance problem in the plasma reactor that would otherwise occur due to use of high frequency RF power applied over a large area wafer such as in the manufacturing of a solar cell. Manufacturing efficiency and productivity of a such a product are improved even in a plasma reactor using a large area wafer.

### BRIEF DESCRIPTION OF THE SEVERAL VIEWS OF THE DRAWINGS

Other features and advantages of the present invention will be apparent from the following detailed description of the invention, taken in conjunction with the accompanying drawings of which:

FIG. 1 illustrates a section of a plasma reactor having divided plasma electrodes according to an exemplary embodiment of the present invention;

FIG. 2 schematically illustrates a graph depicting RF frequencies of RF electric power that is a control reference for a phase control unit of the plasma reactor of FIG. 1, and a plasma electrode unit of the plasma reactor of FIG. 1 allocated to specific phase angles of the RF frequencies; and

FIG. 3 schematically illustrates the divided plasma electrodes of FIG. 1 connected to a plurality of output terminals of the phase control unit, respectively.

### DETAILED DESCRIPTION OF THE INVENTION

This application claims priority of U.S. Prov. Pat. Appl. No. 62/329,488, filed Apr. 29, 2016, the entirety of which is hereby incorporated by reference.

The embodiments described in the specification and the configuration illustrated in the drawings merely correspond to an exemplary embodiment of the present invention, and do not express all the technical spirit of the present invention.

The present invention relates to a plasma reactor, and more particularly to a plasma reactor used for generating a plasma for use in manufacturing products having a large wafer surface area, such as a thin film solar cell. A plasma electrode unit in a plasma reactor is divided into a plurality of parts or electrodes and RF electric power is sequentially applied to the divided plasma electrode parts in response to a phase angle to solve a standing wave problem associated with the plasma electrode of prior art plasma reactors. Absent the divided plasma electrode unit, high frequency RF electric power applied to form the plasma over a large area corresponding to the large wafer surface area can result in plasma imbalance due to a standing wave phenomenon.

Hereinafter, exemplary embodiments of the present invention will be described in detail with reference to the accompanying drawings.

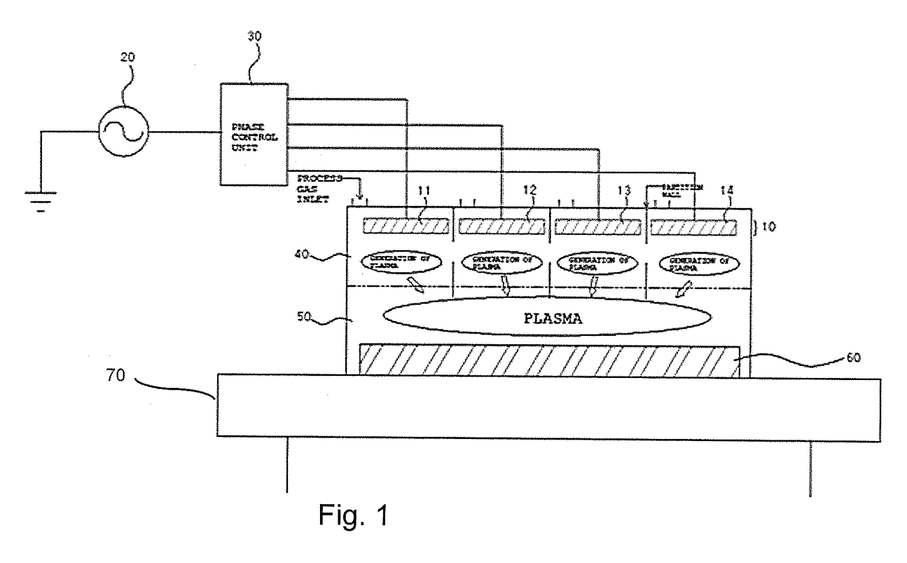

FIG. 1 illustrates a section of a plasma reactor having divided electrodes according to an embodiment of the present invention.

As illustrated in the drawings, the plasma reactor having divided electrodes according to the present invention includes: a buffer chamber 40 into which a process gas is introduced to generate plasma; a process chamber 50 in which the generated plasma is activated; a plasma electrode unit 10 divided into a plurality of parts or electrodes 11, 12, 13, 14 and formed above the buffer chamber 40 for converting the process gas into plasma when RF electric power is applied thereto; a gas supply unit (not illustrated) for supplying the process gas into the buffer chamber 40; an RF electric power supply unit 20 for supplying the RF electric power applied to the plasma electrode unit 10; and a phase control unit 30 for controlling the RF electric power applied to each of the plasma electrodes of the divided plasma electrode unit 10.

The plasma reactor having divided electrodes according to the present invention is configured for operation with a wafer substrate 60 on which is deposited the plasma generated from the buffer chamber 40 by the divided plasma electrodes 11, 12, 13, 14 and activated within the process chamber 50, and a substrate support 70 for supporting the substrate.

In the plasma reactor having divided electrodes according to the present invention, the RF electric power supplied by the RF electric power supply unit 20 is supplied to each electrode of the divided plasma electrode unit 10 through the phase control unit 30, and the RF electric power is sequentially supplied to each of the divided plasma electrodes in correspondence to a specific phase angle or range of phase angles of the RF electric power detected by the phase control unit 30.

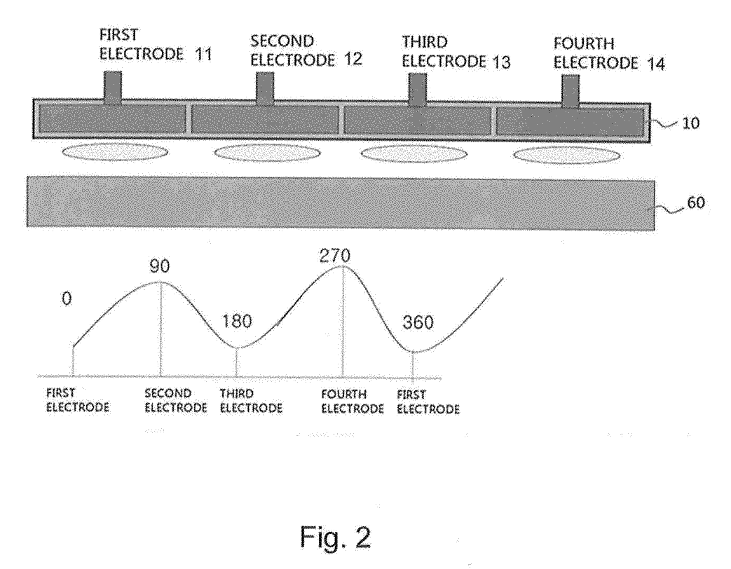

As illustrated in FIG. 1, the plasma electrode unit 10 according to an exemplary embodiment of the present invention is divided into four discrete electrodes 11, 12, 13, 14, but the present invention is not limited thereto, and the plasma electrode unit 10 may have a smaller or larger number of electrodes in other embodiments of the present invention. In the embodiment which will be described below, an embodiment including the plasma electrode unit 10 divided into four parts of FIG. 2, that is, the first electrode 11, the second electrode 12, the third electrode 13, and the fourth electrode 14 will be described.

The configuration of the divided plasma electrode unit 10 is provided to solve a standing wave problem caused by supplying VHF RF electric power to a large area electrode corresponding to the large area wafer 60, and is mutually divided to receive electric power, respectively, and does not cause a standing wave problem as compared with an integral electrode unit according to the related art. In the exemplary embodiment of the present invention, the divided plasma electrode unit 10 may be insulated through a known insulator for mutual insulation between individual electrodes 11, 12, 13, 14.

Furthermore, in the exemplary embodiment of the present invention, the process chamber 50 as well as the buffer chamber 40 may have a plurality of process gas inlets in correspondence to the divided plasma electrode unit 10. The plurality of process gas inlets are allocated to each electrode of the plasma electrode unit 10 to inject a respective process gas with respect to each discrete electrode. To this end, the process chamber 50 as well as the buffer chamber 40 may include one or more partition walls extending downwards between the electrodes such that the process chamber 50 is partially divided into regions of separate gases. A lower side of the buffer chamber 40 is open for deposition of plasma on the substrate within the process chamber 50.

The divided plasma electrode unit 10 is configured to sequentially receive high frequency power at the plural electrodes 11, 12, 13, 14 from the source 20 through the phase control unit 30.

The phase control unit 30 is a constituent element for controlling RF electric power applied to each of the four electrodes of the divided plasma electrode unit 10 and includes a phase detection circuit to detect the phase of the received RF electric power. The phase control unit 30 controls the RF electric power to be applied to the plasma electrode unit 10 according to specific phase angles of the RF electric power, respectively, that is, the phase angles of 0°, 90°, 180°, and 270° in the case of four discrete electrodes. Accordingly, the RF electric power is sequentially applied to the four electrode parts of the divided plasma electrode unit 10 according to phase, or range of phases. Thus, in the example of a divided plasma electrode unit having four discrete electrodes, a first electrode would have RF power applied by the phase control unit when the received RF power is substantially equal to 0°. “Substantially equal” in this context could mean 0° +/− 40° or some smaller range. Thus, each electrode receives RF power in sequence, whereby only one electrode is energized at a time.

As a result, the process gas reacts in each of the electrode parts or electrodes in the divided plasma electrode unit 10 to generate plasma, and finally generates plasma corresponding to the entire large area wafer 60. In this case, because the plasma is separately generated by each of the electrode parts of the divided plasma electrode unit 10, each reaction area is relatively small. Thus, it is not necessary to apply high-frequency RF power, whereby the non-uniformity problem of plasma associated with the prior art is solved and uniform plasma corresponding to the large area wafer 60 may be formed.

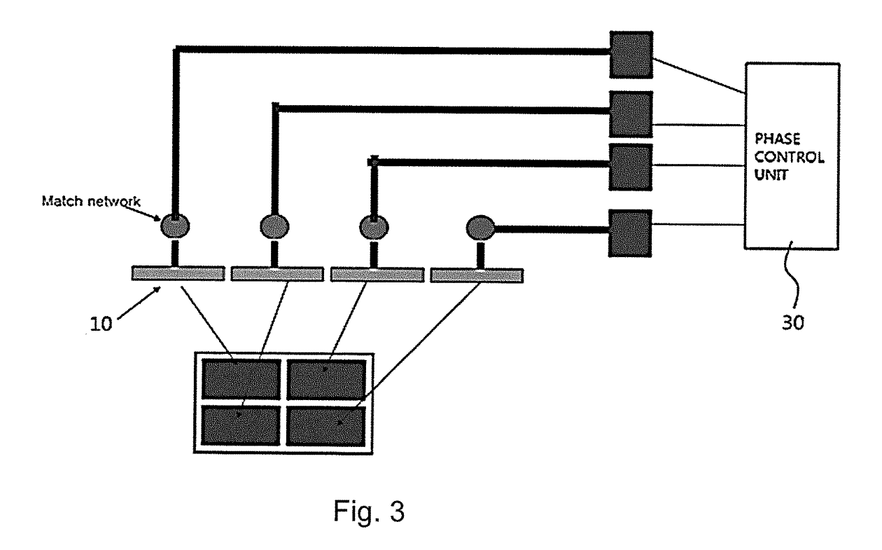

FIG. 2 illustrates a graph depicting RF electric power frequency that is a control reference for the phase control unit 30, and schematically illustrates the plasma electrode unit 10 discrete electrodes 11, 12, 13, 14 allocated to respective frequency phase angles. FIG. 3 schematically illustrates the divided plasma electrode unit respectively connected to a plurality of output terminals of the phase control unit 30. While the plural electrodes 11, 12, 13, 14 are schematically depicted in FIGS. 1 and 2 as being disposed in a linear array, this is for ease of illustration only. In fact, for use with a large wafer that may be rectangular or square, the electrodes are preferably disposed in a grid pattern, such as shown in FIG. 3.

As illustrated, the phase of the RF electric power applied to the phase control unit 30 is detected by the phase control unit 30. The phase control unit 30 matches the detected specific phase angles of the RF electric power, for example, 0° (360°), 90°, 180°, and 270°, with the divided plasma electrode unit 10, and thereafter, controls the frequency of the current applied to the divided plasma electrode unit 10 by the phase control unit according to the control reference phase angles described above.

The phase control unit 30 includes an integrated circuit including a rectifier circuit for processing applied electric power, a phase angle detection circuit, and a plurality of output terminals each connected to a respective electrode of the divided plasma electrode unit 10 for outputting electric power in correspondence to the detected phase and the control reference. Accordingly, if RF electric power is applied to the phase control unit 30, a phase angle is detected through a phase angle detection circuit via a rectifier circuit in the phase control unit 30, and RF electric power is applied to one of the divided plasma electrodes corresponding to the detected phase angle.

As illustrated in FIG. 3, in an exemplary embodiment of the present invention, RF electric power of 5 KW having a frequency of 60 MHz, which is relatively low as compared with VHF, is applied to the divided plasma electrodes, respectively. The RF electric power applied to each divided, insulated plasma electrode produces plasma, but because the activity is sequentially and consistently performed, the same effect as obtained when electric power of a total of 20 KW is supplied to a conventional electrode can be obtained.

The plasma reactor having the divided electrodes according to the present invention solves a standing wave problem and a plasma imbalance problem that occurs due to use of a large area wafer 60 such as in the manufacturing of a solar cell through the above configuration. Accordingly, the present invention solves all the disadvantages of the plasma reactor according to the related art, and enhances a manufacturing efficiency of a product even in the plasma reactor using a large area wafer 60, thereby improving productivity.

Although an exemplary embodiment of the plasma reactor having divided electrodes according to the present invention has been described in detail, it is merely a specific example for illustrating the general concepts of the present invention, and is not intended to limit the scope of the present invention. It is clearly understood by those skilled in the art to which the present invention pertains that modifications based on the technical spirit of the present invention can be made in embodiments other than the disclosed embodiment.

What is claimed is:

1. A plasma reactor for generating plasma, the plasma reactor comprising:
a buffer chamber;
a divided plasma electrode unit comprising plural discrete electrodes and disposed within the buffer chamber;
at least one process gas inlet for receiving a respective process gas and for injecting the respective process gas into the buffer chamber proximate the discrete electrodes;
a process chamber in which a plasma can be formed by the discrete electrodes selectively energizing the process gas;
a substrate support disposed at a lower end of the process chamber for supporting a substrate onto which the plasma is deposited;
an RF electric power unit for supplying RF electric power; and
a phase control unit for sequentially applying RF electric power, received from the RF electric power unit, to each of the discrete electrodes of the divided plasma electrode unit.

2. The plasma reactor of claim 1, wherein the phase control unit associates each discrete electrode of the divided plasma electrode unit with a phase angle or range of phase angles of the RF electric power, detects the phase of the RF electric power received from the RF electric power unit, and selectively applies the RF electric power to the discrete electrode of the plasma electrode unit associated with the detected phase angle of the RF electric power.

3. The plasma reactor of claim 2, wherein
the divided plasma electrode unit includes a first plasma electrode, a second plasma electrode, a third plasma electrode, and a fourth plasma electrode that are spaced apart from each other in a substantially horizontal plane, and
the phase control unit sequentially associates the each discrete electrode of the divided plasma electrode unit with one of the phase angles of substantially 0° (360°), 90°, 180°, and 270° of the RF electric power.

4. The plasma reactor of claim 1, wherein the discrete electrodes of the divided plasma electrode unit are:
spaced apart from each other in a substantially horizontal plane;
arrayed in correspondence with a shape of a wafer to be disposed on the substrate support; and
are insulated from each other through an insulator.

5. The plasma reactor of claim 1, wherein the at least one process gas inlet comprises plural process gas inlets, each process gas inlet being associated with a respective one of the plural discrete electrodes.

6. The plasma reactor of claim 5, further comprising:
a partition wall extending downward from the top of the buffer chamber and between the plural discrete electrodes within the buffer chamber for isolating the process gases from each other, the buffer chamber is downwardly open to allow the process gases to be energized by the respective discrete electrodes and to form the plasma therefrom within the process chamber.
